(19) United States
(12) Patent Application Publication
(10) Pub. No.: US 2014/0273814 A1
(43) Pub. Date: Sep. 18, 2014

(54) HIGH FREQUENCY MIXER, METHOD AND SYSTEM

(71) Applicant: L-3 COMMUNICATIONS CORP., New York, NY (US)

(72) Inventors: Loren Edward Ralph, Citrus Heights, CA (US); Eddie Rodgers, Folsom, CA (US); Jeffrey Scot Muir, Colfax (US)

(73) Assignee: L-3 COMMUNICATIONS CORP., New York, NY (US)

(21) Appl. No.: 13/840,816

(22) Filed: Mar. 15, 2013

(51) Int. Cl. H03D 7/14; H04B 7/185

(52) U.S. Cl. CPC H03D 7/1466; H04B 7/18513
USPC 455/12.1

(57) ABSTRACT

A thin film circuit, particularly desirable for satellite communications, mixes RF and an LO giga-hertz-range input signals to yield an IF signal by splitting the LO and RF signals into two, with a 180 degree phase shift introduced into one of the resulting signals. The LO and RF signals are then each mixed in parallel mixers. The outputs of the mixers have the IF signal with spurious (spur) signals in frequencies that are multiples of the frequencies of the RF or LO signals. The outputs are mixed together so that some of the spur signals cancel each other out and the IF signals are added in phase.

### FIELD OF THE INVENTION

The invention relates generally to radio transmitters utilizing a mixer to produce an output signal of a given frequency. In particular, the invention relates to circuits containing mixers that combine a first signal LO with a second signal RF to yield a third signal IF, especially in a relatively high-frequency application. More particularly, this invention relates to such circuits for use in satellites.

### BACKGROUND OF THE INVENTION

A common way to combine two input signals to produce an output signal is to employ a mixer. A key feature of a mixer circuit is one or more mixing elements, which generally comprise a nonlinear device such as a diode, field effect transistor, or bipolar junction transistor.

Mixing elements combine two frequency inputs to yield other frequency outputs, which vary according to the features of the particular mixing elements. In particular, mixing elements are designed to output second order frequencies, which include the sum and difference of the two input signal frequencies. In common usage, an LO signal and an RF signal enter the mixer element, which then outputs an IF signal that is either the sum or difference of the input frequencies.

In telecommunications, mixers receive a radio frequency input signal (RF) and a signal from a local oscillator (LO), and combine them to produce an output signal. The output signal comprises the Intermediate Frequency signal (IF) at a frequency that is either the difference or the total of the frequencies of the RF and LO signals. The IF signal is typically the useful or desired portion of the output signal, and it carries the information of the RF signal a different desired frequency.

Because mixers are non-linear, mixers output additional signals with frequencies other than the desired IF signal. The additional frequencies are various other combinations of the RF and LO frequencies, typically multiples of the RF or LO frequencies, or sums and differences of multiples of the input signal frequencies. These mixer by-products are referred to as spurious frequencies (“spurs”), or collectively as intermodulation distortion (IMD). Typically these other frequency outputs are unwanted, and serve only as noise or interference.

In addition, depending on the frequencies of the RF, LO and IF signals, the spurs may be very close to the frequencies of the output signal. As an example, a potential problem encountered can be seen in the graph of FIG. 4, which shows the inputs and some of the outputs of a mixer. The mixer receives a radio-frequency (RF) input signal 201 at a frequency of 30 GHz and a local oscillator (LO) signal 202 with a frequency of 9.5 GHz. The mixer produces spurs as multiples of the LO frequency and an intermediate frequency (IF) signal 203 with a frequency that is the difference between the frequencies of RF signal 201 and LO signal 202, i.e., 30 GHz-9.5 GHz=20.5 GHz. However, one of the spurs produced by the mixer is a harmonic signal 204 of the LO signal 202, with a frequency two times the LO frequency, i.e., 2×9.5 GHz=19 GHz. This is fairly close to the IF frequency of 20.5 GHz.

A common method to reduce the spurious output of the mixer while retaining the desired IF signal is to exclude the unwanted frequencies through the use of high- or low-pass filters, either alone or together as band-pass or notch filters, that filter out some of the spurs but let the desired frequency pass.

However, in the example, the two frequencies are so close that to try to filter out the 2×LO spur and pass the IF signal is difficult. In addition, the use of one or more filters of this type has the drawback of cost and weight of the filter components. The added weight is especially an issue in the context of satellite-based systems where weight is a major cost item, some estimates being that every gram of weight launched for a satellite represents thousands of dollars in cost.

### SUMMARY OF THE INVENTION

It is therefore an object of the invention to provide a mixer circuit, especially one operating at above one GHz, that overcomes the drawbacks of the prior art.

It is also an object of the invention to provide a circuit configured for mixing RF and LO signals with an output with reduced harmonics of the LO signal, especially the 2×LO harmonic, without the use of filters, especially such a circuit that is of a lightweight and hardened design for efficient use in space.

It is further an object of the invention to provide a novel mixer topology that rejects spurious frequency by-products of mixed signals.

According to another aspect of the invention, a mixer circuit comprises a first component configured to receive a first input signal having a first frequency of at least one gigahertz (GHz) and to output two output signals at the first frequency that are 180 degrees out of phase with respect to each other. The circuit further comprises first and second mixer elements each connected with the first component and configured to each receive a respective one of the output signals from it to each receive a second input signal having a second frequency of at least one gigahertz and to each mix the respective output signal with the second input signal so as to derive respective mixer output signals. Each of the mixer output signals includes a primary output signal at a third frequency that is a sum or a difference of the first and second frequencies, and at least one spur signal that is a harmonic of the first or second input signal, with either the primary output signals or the spur signals are 180 degrees out of phase with respect to each other. A signal combining component is connected with the first and second mixer elements and configured to receive and combine the mixer output signals so as to produce a combined output signal comprising the primary output signal, and in which the spur signals partially or totally cancel each other.

According to another aspect of the invention, a method of generating a signal comprises supplying a first signal having a first frequency above 1 GHz, and processing the first signal so as to produce two first output signals that are 180 degrees out of phase relative to each other. The method further comprises supplying a second signal having a second frequency above 1 GHz, and mixing each of the first output signals with the second signal in respective mixers so as to produce two mixer product signals. Each mixer product signal has a respective primary output signal with a third frequency, where the third frequency=first frequency−second frequency or the third frequency=first frequency+second frequency, and a spur signal having a spur frequency that is a multiple of the second frequency. Either the primary output signals or the spur signals are out-of-phase with each other in the mixer product signals. The mixer product signals are combined such that the spur signals substantially cancel each other out and so as to yield a combined signal comprising a combination of the primary output signals.

According to still another aspect of the invention, a telecommunication system comprises a source of radio-frequency (RF) signal and a source of local-oscillator (LO) signal, both of the signals having respective frequencies in the gigahertz frequency range. A light-weight mixer circuit is supported within a housing and configured for use on a satellite in space. The mixer circuit comprises a thin-film ceramic substrate. A thin film RF balun is on the substrate and has an RF signal input connected with the source of the RF signal. The RF balun has first and second RF signal outputs transmitting first and second RF output signals respectively, the second RF output signal being substantially 180 degrees out of phase with respect to the first RF output signal. The first and second RF output signals have substantially equal amplitudes.

First and second thin-film mixer elements are also on the substrate. Each mixer element comprises a balanced mixer using a beam lead quad diode formed on the substrate and has two mixer inputs and one mixer output. Each mixer element has one of the mixer inputs thereof connected with a respective RF signal output and receiving the respective RF output signal from it. A thin-film LO transmission structure on the substrate provides electrical communication between the source of the LO signal and each of the mixer elements, receiving the LO signal and transmitting the LO signal as first and second LO input signals to the other of the inputs of the first and second mixers respectively. The LO transmission structure including an LO phase adjuster element adjustable so that the first and second signal inputs are substantially in phase with each other at the inputs of the mixer elements. The first and second mixer elements provide first and second mixing output signals, respectively, at their mixer outputs. The first and second mixing output signals include mixer product signals that include an IF signal with a frequency substantially equal to a difference between the frequency of the LO signal and the frequency of the RF signal frequency, and a spur signal having a frequency that is an integral multiple of the frequency of the LO signal. The IF signal of the first mixing output signal at the first mixer output is substantially 180 degrees out of phase with the IF signal of the second mixing output signal at the second mixer output, and the spur signal of the first mixing output signal at the first mixer output is substantially in phase with the spur signal of the second mixing output signal at the second mixer output.

A thin film output balun is supported on the substrate and has an output and two inputs. Each of the inputs is connected with a respective mixer output and receives the respective mixer output signal from it. The output balun produces a shifted mixer output signal from one of the mixing signal outputs. The IF signal in the shifted signal is substantially in phase with the IF signal of the other of the mixer output signals and the spur signal in the shifted signal is substantially 180 degrees out of phase with the spur signal of the other of the mixer output signals. The output balun combines the shifted mixing signal output with the other of the mixing output signals so as to produce a circuit output signal wherein the spur signals substantially cancel each other out and the IF signals are combined substantially in phase. The circuit output signal is transmitted via the output of the output balun.

According to one of the embodiments, the circuit is of thin-film construction which possesses a multilayer structure. This embodiment has a support substrate, with no air gap below it. The mixing elements may be built all on the top side of the substrate without cavities beneath the substrate. The signal paths created for each signal in the circuit are chosen such that the circuit achieves maximum attenuation of the undesired harmonics of the LO source in the IF output. The construction is easily modeled, allowing for predictable performance, and it is also scalable to integrated circuit materials. This modeling can be performed using existing non-linear circuit software.

The invention is therefore easily tuned to various frequencies. In particular, the invention may be used in satellite communications applications on several commonly used frequency channels such as, e.g., the KA, K, and KU bands.

Other objects and advantages of the invention will become apparent from the specification herein, and the scope of the invention will be set out in the claims.

### BRIEF DESCRIPTION OF THE DRAWINGS

FIG. 1 shows a diagram illustrating a communications satellite orbiting the Earth and both receiving and transmitting radio signals to and from ground stations;

FIG. 2 is a diagram of the general functional circuitry of a telecommunications satellite such as in FIG. 1;

FIG. 3 is a diagram of a mixing circuit according to the invention;

FIG. 4 is a graph of exemplary inputs and outputs of mixers according to the invention.

FIG. 5 is a diagram showing the pattern of thin-layered materials on a substrate for a mixer circuit according to the invention.

### DETAILED DESCRIPTION

For the purposes of promoting and understanding the principles disclosed herein, reference is now made to the preferred embodiments illustrated in the drawings.

The lightweight mixer design described here is particularly applicable to circuitry used in satellites to process high-frequency wireless radio signals. Weight is a particular concern in orbital devices, due to the high cost of launch based on weight. An exemplary system is therefore shown herein on a satellite, although it will be understood that the invention may have a wide range of terrestrial uses as well.

Referring to FIG. 1, a satellite 100 is shown in orbit above the Earth 200 (or potentially some other celestial body). The satellite 100 is provided with antennae 101 and 102. According to the embodiment shown, antenna 101 receives one or more wireless radio signals indicated generally at 104 from an earth station indicated at A. These radio signals are normally high-frequency RF signals, i.e., with a frequency of 10 to 50 GHz, and may be television, audio, telephonic, data or electronic command communications to the satellite, or virtually any kind of communication signal, all of which are well known in the art.

Satellite 100 also transmits a wireless high-frequency RF signal 105 back to earth station B via antenna 102. The transmitted signals may also be any type of transmission or broadcast, such as a transmission of video from a camera on the satellite.

Most preferably, the satellite 100 is a communications satellite that functions as a “bent pipe” system, i.e., the satellite receives video, audio or data content via the upload signals 104, does some amplification, encryption, or other on-board processing in the satellite's internal circuitry, and then transmits the content back to Earth in signals 105, which can be at a frequency that is the same as or different from the frequency of signals 104.

The satellite 100 has internal circuitry that receives and processes the radio signals 104 and otherwise controls the operation of the satellite. The on-board circuitry is preferably in a hermetically sealed environment inside a carrier or protective case inside the satellite housing 107. The housing 107 is preferably of stainless steel and shields the internal components of the satellite from radiation and other potentially deleterious influences found in space. In addition, the satellite circuitry may be hardened by methods well-known in the art to prevent damage to the circuitry by radiation outside the Earth's atmosphere.

FIG. 2 shows a schematic diagram of the general internal operation of the satellite 100. Receiver antenna circuitry 3 is connected with antenna 101 and receives the radio signal over a conductor linking them. Receiver antenna circuitry 3 transmits a raw received RF signal along a conductor to incoming signal process circuit 5, which converts the RF signal to a different, usually lower, frequency for processing on the satellite. Generally, down-conversion allows for easier manipulation, amplification or other processing of the content of the RF signal than at the high frequency at which it is received.

The converted RF signal is transmitted by conductor to the internal satellite circuitry 7 for any kind of processing in accord with the function of the satellite, e.g., as data, as commands for control of the satellite 100 or as content re-transmission back to Earth. For example, where the content is television signals, the program content in the RF signal may be amplified and then possibly encrypted to yield a processed signal for transmission.

The outgoing signal or signals generated by the internal satellite electronics 7 are transmitted over an electrical conductor to outgoing signal process circuit 9. This circuitry 9 changes the frequency of the signal from internal electronics 7 to a transmission signal at a transmission frequency, usually higher than the incoming frequency. The transmission signal is sent by an electrical conductor to transmitting antenna circuitry 11, which wirelessly transmits it via antenna 102 to a receiver or receivers on Earth.

FIG. 3 is a more detailed block diagram of a circuit according to an aspect of the invention. This circuit is used in down-conversion circuitry of incoming process circuit 5 or in the outgoing signal process circuit 9.

A radio frequency (RF) signal source 13, e.g., the receiver antenna 101 and associated circuitry 103, is connected to an input of an input balun 15 and supplies an RF signal to it. The input balun 15 has two outputs 17 and 19. Internally the balun 15 splits the RF signal. At output 17, the balun 15 outputs a first RF signal that has a phase shift φ of zero (0) degrees, and at output 19, balun 15 outputs a second RF signal that has been delayed or otherwise processed so as to impart to it a 180-degree phase shift φ. The two RF signals produced are therefore 180 degrees out-of-phase, or antiphase, relative to each other.

A local oscillator (LO) 21 provides a -sinusoidal local-oscillator signal LO to the circuit on conductor 23, which has a simple branch into two conductors 25 and 27, which both carry a respective split LO signal. Both of the LO signals have a phase shift φ of zero degrees, i.e., no phase shift, and are perfectly in phase with each other.

The frequencies of the LO and RF signals are above 1 GHz. Generally, the circuit shown is used with Ka band (26.5 to 40 GHz signal) downconverters and receivers. It is also scalable to other frequency applications, such as K band (20 to 40 GHz) or Kᵤ band (12 to 18 GHz) applications. For the receiving signal processing circuit 7, the RF signal preferably has a frequency in the range from 10 to 40 GHz, and most preferably a frequency of approximately 30 GHz, and the LO signal has a frequency in the range from 5 to 20 GHz, and most preferably a frequency of approximately 9.5 GHz.

Mixer element 1, indicated at 31, has two inputs. One of the inputs is connected with line 17 and receives the first RF signal from it with zero-degrees phase shift φ. The other input is connected with line 25 and receives one of the LO signals from it, also with zero-degrees phase shift φ. Mixer element 2, indicated at 32, has two inputs as well. One of these inputs is connected with line 19 and receives the second RF signal from it with 180-degrees phase shift φ, and the other input is connected with line 27 and receives from it the other LO signal with zero-degrees phase shift φ.

The mixer elements 31 and 32 constitute a 180 degree balanced set of mixers, and both have essentially identical configurations as will be described below. The mixer elements 31 and 32 mix the RF and LO signals supplied to them at the inputs and produce an IF signal provided at the respective mixer outputs 33 or 35. The mixer output signals each comprise a number of combined signals, including an IF signal that has a frequency that is the difference or the sum of the frequencies of the RF and LO signals. Also, a number of additional signals with other frequencies are typically produced by the mixing process and are present in the mixer output signals with the IF signal. These signals include spur signals formed as second and higher-order harmonics of the LO or RF input signals.

FIG. 4 illustrates some of the signals applied to or produced by the mixer elements 31 and 32 where the circuit is used to down-convert 30 GHz RF signal 201 to a lower frequency by mixing with a 9.5 GHz LO signal 202. In that case, the mixer output signal includes the desired output signal, IF signal 203, which has a frequency of 20.5 GHz. The mixer output signal also includes spurs and noise, including spur signal 204, which is the second order harmonic of the LO signal input to the mixer, with a frequency of 2*9.5 GHz=19 GHz, and disagreeably close to the desired IF signal at 20.5 GHz.

The mixer elements 31 and 32 both produce the IF signal 203 and the second LO harmonic 2*LO spur signal 204 in their respective outputs. However, because the mixer elements 31 and 32 receive the respective RF input signals 180-degrees out of phase with each other, the resulting IF signals in the two mixer output signals are also 180-degrees out of phase to each other. In contrast, the LO signals received by the mixer elements 31 and 32 are in-phase with each other, i.e., zero degrees out-of-phase and the 2*LO second harmonic spur signals 204 are also in-phase with each other in the two mixer output signals.

This difference in phase-shift of the desired IF signal and the second LO harmonic spur signal allows for removal of the spur signal. This is accomplished by supplying the mixer output signals along conductors 33 and 35 to two inputs of output balun 37, which is configured to give a phase shift of 180 degrees to one of the signals at one of its inputs, and then to combine that phase-shifted signal with the signal from the other input. The combined-signal result is transmitted at the single output of balun 37.

The input signals to the balun 37 in the circuit of FIG. 3 include the IF signals in antiphase and the second spur signals in phase. When one of these mixer output signals is given a 180-degree phase shift, the result is that the IF signals are placed in phase and the spur signals are put 180-degrees out of phase. As a result, when the shifted signal and the other signal at the balun 37 input are combined, the out-of-phase spur signals partly or totally cancel each other out. Any of the other noise or spur signals in the mixer output signals that are in-phase between the two mixer output signals (e.g., higher order even harmonics of the LO signal) will also cancel each other out in balun 37.

The IF signals, however, are 180 degrees out of phase in the mixer output signals, so when one IF signal is phase-shifted 180 degrees and the two signals are combined, the IF signals are combined in phase, resulting in a strong IF signal. A final balun output signal, including the IF signal, is transmitted by conductor to subsequent processing of the IF signal by circuitry on the satellite, or to be transmitted via an antenna, generally indicated at 39.

The circuit of the invention is sealable to frequencies other than the ranges of frequencies described herein. This circuit is beneficial for eliminating spur signals without relying on heavy filters, and with a greater degree of precision. For example, it is possible to use the present circuit where the LO signal frequency is 9.8 GHz and the RF signal frequency is 30 GHz. The resulting IF signal frequency is 20.2 GHz, while the second LO harmonic spur signal has a frequency of 19.6 GHz, a separation of only 0.6 GHz, which would be very difficult to carve out with a filter. Nonetheless, the phase-shifted mixing circuit described here allows for effective mixing of the signals even where the harmonic spur frequency and the IF signal frequency are separated by as little as 0.5 or 0.6 GHz.

FIG. 5 is a detailed plan view of an embodiment of the mixer circuit that has been described more generally above. The baluns 15 and 37 and the mixer elements 31 and 32 are generally indicated by the same reference numbers as in FIG. 3, as are the conductors or contacts identified in FIG. 3.

The circuit shown is manufactured using a multi-layer thin-film approach in which a layered material is etched or otherwise selectively removed so as to form a lightweight circuit. The process and materials used are available from the company Applied Thin-Film Products, with a place of business at 3439 Edison Way Fremont, Calif. 94538, and a website at www.thinfilm.com. The use of a multilayer structure as shown allows the use of a thick support substrate, with no air gap below it, which is different from typical balanced mixer designs.

The circuit may be a single component as shown, or may be part of a larger circuit. The circuit can also be manufactured using microwave integrated circuit technologies.

The circuit 41 is supported on a ceramic substrate sheet 43, preferably of a consistent thickness. The substrate material is typically polished alumina, with a dielectric constant of 9.9.

The RF input 13 and the LO input 21 are thin film gold transmission lines. The RF signal input 13 connects with the input of input 180° balun 15. Input balun 15 is of known design, and is comprised of gold film conductors overlying a layer of polyimide material 45 on the substrate 43. Input balun 15 also has ground connections 47 that extend through the substrate 43 to contact ground on the other side of the substrate 43. Input balun 15 splits the incoming RF signal and produces balanced output such that the split RF signals are transmitted to respective gold-film lines 17 and 19, with the RF signal on line 17 having a 180 degree phase shift, as described above. The balun 21 is constructed to maximize its performance at a set RF frequency or frequency range, and its design may include structure that substantially prevents impedance from interfering with transmission of the RF signal. The balun 15 in the embodiment shown can split and phase shift RF signals in a frequency range of 23 to 34 GHz, appropriate in the present embodiment configured for use with an RF with a frequency of 30 GHz. The design of course can be modified for different RF frequencies if appropriate.

LO signal input contact 21 connects to gold-film line 23, which leads to an LO signal splitting structure 49, also of gold film. Splitting structure 49 includes adjustment structures 51 and 53, which may be used to adjust the precise distance that the LO signal must travel to the mixer elements 31 and 32. A resistor 55 bridges the split LO signal lines 25 and 27 and balances the split signals on lines 25 and 27. Line 25 proceeds via jumper 57 to mixer element 31 and line 27 proceeds to mixer element 32, passing through another adjustment structure 59, which provides for smaller phase adjustment than adjustment structures 51 and 53. Preferably this is done to ensure that the LO signals are configured to arrive at the mixers 31 and 32 substantially in phase with each other.

Mixer elements 31 and 32 are essentially identical configurations. The mixer structure is effectively all on the upper side of the substrate 43, not suspended, without a cavity in the structure. Each mixer 31 or 32 comprises a mixer input balun 61 connecting with a diode 63.

Each of the mixer input baluns 61 has a single input connected with a respective RF signal line 17 or 19. The mixer input baluns 61 are also of gold film overlying a layer of polyimide material. The mixer input baluns 61 have access to ground through vias 69, which extend through to the other side of the substrate 43 to contact ground.

Diodes 63 are chips inserted into the circuit 41. The diodes 63 are commercially available crossover quad diodes connected between the mixer input baluns 61 to respective LO/IF diplexer baluns 65 through gold-film conductors 71. LO signal lines 25 and 27 also each connect across a resistor 77 with respective diplexer baluns 65 and supply the LO signals thereto. Resistors 77 make the diplexer baluns 65 less sensitive to the drive level of the LO signals.

The LO/IF diplexer baluns 65 are also formed of gold film on a polyimide layer 73, and vias 75 extend through the substrate 43 and provide connection to ground for the baluns 65. The diplexer baluns 65 each has a balun loop 79 that is sized to correspond to the diode 63 configuration and parameters, as is well known in the art.

The mixer output signals are each transmitted to respective outputs of the diplexer baluns 65 to gold-film lines 33 and 35. As described above, the IF signals in these mixer output signals are out of phase relative to each other, and the second LO harmonic spur signals in the two mixer output signals are in phase relative to each other.

That situation continues until the mixer output signals reach the output 180° balun 37. Balun 37 is also formed of gold film on a polyimide layer 81, and it has vias 83 to ground extending through the substrate 43. As described previously, the balun 37 introduces a 180 degree phase shift to the first mixer output signal, making the spur signals out-of-phase, and the two mixer output signals are then combined so that the spur signals cancel each other without affecting the IF signals. The output balun 37 is configured in the present embodiment to process signals that fall in the frequency range of 16 to 24 GHz, suitable for, e.g., an IF frequency of 20.5 GHz and a second LO harmonic of 19 GHz, as has been discussed herein. A balun with a different configuration suited to a different functional frequency range, e.g., a higher range, may be employed if circuit 41 is to be used for a higher frequency output, such as up-converting the frequency of an on-board signal for broadcasting.

Output balun 37 transmits the signal that is derived from combining the mixer output signals along conductor 85 to the IF contact 39, where the circuit 41 connects with other electronics, not shown, that process the IF signal or transmit it wirelessly, as has been described above.

Commonly, mixer circuits are made with metal conductor patterns on both sides of a relatively thin substrate, with coupling through the substrate. The influence of ground on, e.g., balun structures of the underside of the circuit is prevented by providing a separating cavity between ground and the metal pattern on the substrate.

In contrast, in the present design, the coupling of the gold conductors in the balun or mixer structures takes place in the polyimide layer, which is very thin, e.g., 4 microns to 5 microns thick, preferably about 4.5 microns thick. The substrate used in the present design is a thicker substrate, e.g., 10 to 20 times thicker than usual, 200 to 300 microns thick, most preferably about 254 microns thick. This larger thickness separates the ground on one side of the substrate from the circuitry on the other side, eliminating the need for a cavity or air clearance, with the result that the structure is markedly stronger.

The mixer circuit described herein can be used in either upconversion or downconversion applications above one GHz. It therefore may be used primarily as a circuit in a device for receiving RF signals or transmission of IF signals, or both. It also should be clear that the circuit may be used in combination with other equipment, e.g. where additional components receive an RF signal from an antenna, modify the signal received, and then pass the modified signal to the RF port of a circuit of the present design. Similarly, additional equipment may receive the IF signal output and modify it before transmission, e.g. by amplification of the signal with an electronic amplifier.

Although adopting a standard convention of referring to one input signal as the RF, the present invention is agnostic as to whether the RE signal is broadcast and later received via antenna, if it exists entirely within a contained system and is never transmitted wirelessly before or after it is processed by a circuit or circuits as herein described, or if it undergoes one or more transformation steps before or after mixing by a circuit as described. The RF signal may contain additional frequencies in some instances, and may use amplitude or frequency modulation, and may otherwise vary widely in form.

It should also be noted that the present invention may be practiced in several other variations. For example, if additional mixing elements are desired, the circuit may be adapted to their use by providing additional parallel paths of RE and LO signals to the additional mixing elements, and then from the mixing elements to the final output balun. The signals provided to the various mixer elements are then adjusted such that the vector sum of the mixer products at the output balun results in substantial cancellation of the LO and 2*LO output signals, while retaining the desired IF output signal.

Where the topography requires, two intersecting electrical paths in the circuit may avoid electrical contact by the use of jumpers, such as ribbon jumper 57 or 87.

It should be understood that terms used herein are intended as descriptive rather than limiting, and that, although the invention has been described in conjunction with the specific embodiment set forth above, those skilled in the art in light of the disclosures set forth herein may make many alternatives, modifications and variations therein without departing form the spirit of the invention.

What is claimed is:

1. A mixer circuit comprising:
a first component configured to receive a first input signal having a first frequency of at least one gigahertz (GHz) and to output two output signals at the first frequency, wherein the output signals are 180 degrees out of phase with respect to each other;
first and second mixer elements each connected with the first component and configured to each receive a respective one of the output signals therefrom, to each receive a second input signal having a second frequency of at least one gigahertz and to each mix the respective output signal with the second input signal so as to derive respective mixer output signals, wherein each of the mixer output signals includes a primary output signal at a third frequency that is a sum or a difference of the first and second frequencies, and at least one spur signal that is a harmonic of the first or second input signal, and either the primary output signals or the spur signals are 180 degrees out of phase with respect to each other; and
a signal combining component connected with the first and second mixer elements and configured to receive and combine the mixer output signals so as to produce a combined output signal comprising the primary output signal, and in which the spur signals partially or totally cancel each other.

2. The invention according to claim 1 and further comprising
an RF source supplying an RF signal with an RF frequency of at least one GHz as the first input signal to the first component,
an LO source supplying a local oscillator signal with an LO frequency of at least one GHz to the first and second mixer elements;
the mixer elements producing an IF signal with an IF frequency of at least one GHz as the primary output signal; and
wherein the IF frequency is between the LO frequency and the RF frequency.

3. The invention according to claim 2, wherein the RF frequency is from 25 to 35 GHz, and the LO frequency is from 5 to 15 GHz.

4. The invention according to claim 1, wherein the first component comprises a balun having a first input lead and first and second output leads, and configured to transmit the first input signal as the first output signal with zero-degree phase shift and as the second output signal with 180-degree phase shift.

5. The invention according to claim 4 wherein the mixer elements are configured to transmit the primary output signals 180 degrees out of phase with respect to each other and the spur signals in phase with each other; and
wherein the signal combining component is a second balun with two inputs each connected so as to receive a respective one of the mixer output signals, the combining component being configured to introduce a 180 degree phase shift into one of the mixer output signals and to then combine the mixer output signals so as to yield the combined output signal at an output of the second balun.

6. The invention according to claim 1, wherein the signal combining component is connected to an antenna structure including an amplifier and antenna configured to amplify and transmit the combined output signal wirelessly.

7. The invention according to claim 1, and further comprising a receiver antenna arrangement configured to receive an RF signal and to supply the RF signal to the first balun as said first input signal, and wherein said mixer circuit acts as a downconverter of the RF signal.

8. The invention according to claim 1, wherein the mixer circuit is supported on a substrate and is formed by a thin-film process.

9. The invention according to claim 1, wherein the mixer circuit is supported in a structure configured to be launched as a satellite.

10. A method of generating a signal, said method comprising:
supplying a first signal having a first frequency above 1 GHz;
processing the first signal so as to produce two first output signals that are 180 degrees out of phase relative to each other;
supplying a second signal having a second frequency above 1 GHz;
mixing each of the first output signals with the second signal in respective mixers so as to produce two mixer product signals, each mixer product signal having a respective primary output signal with a third frequency, wherein the third frequency=first frequency−second frequency or the third frequency=first frequency+second frequency, and a spur signal having a spur frequency that is a multiple of the second frequency, wherein either the primary output signals or the spur signals are out-of-phase with each other in the mixer product signals;
combining the mixer product signals such that the spur signals substantially cancel each other out and so as to yield a combined signal comprising a combination of the primary output signals.

11. The invention according to claim 10, wherein said supplying the first signal includes receiving an RF signal via an antenna and transmitting the RF signal via a conductor to a balun that performs said processing thereof.

12. The invention according to claim 10, wherein said processing, comprises splitting the signal into two identical intermediate signals, and imparting to one of the intermediate signals a 180-degree phase shift.

13. The invention according to claim 12, wherein, in the mixer product signals, the primary output signals are 180-degrees out of phase with respect to each other, and the spur signals are in phase with each other; and
wherein the combining is performed by transmission of the mixer product signals to a balun having two inputs, said balun introducing a 180-degree phase shift in one of the mixer product signals after which the mixer product signals are combined, with the primary output signals being combined in phase, and the spur signals canceling each other out as 180-degrees out of phase.

14. The invention according to claim 10, wherein
the first signal is an RF signal with an RF frequency, the second signal is a local oscillator signal with an LO frequency, and the primary output signal is an IF signal with an IF frequency that is between the LO frequency and the RF frequency.

15. The invention according to claim 14, wherein the RF frequency is from 10 to 40 GHz, and the LO frequency is from 5 to 20 GHz.

16. The invention according to claim 10, and further comprising transmitting the combined signal via an antenna assembly.

17. The invention according to claim 10, wherein the processing, mixing and combining are performed on a mixer circuit formed by a thin film process.

18. The invention according to claim 10, wherein said method is performed on a satellite in orbit.

19. A telecommunication system comprising:
a source of radio-frequency (RF) signal and a source of local-oscillator (LO) signal, both of said signals having respective frequencies in the gigahertz frequency range;
a light-weight mixer circuit supported within a housing and configured for use on a satellite in space, said mixer circuit comprising:
a thin-film ceramic substrate;
a thin film RF balun on the substrate and having an RF signal input connected with the source of the RF signal, said RF balun having first and second RF signal outputs transmitting first and second RF output signals respectively; the second RF output signal being substantially 180 degrees out of phase with respect to the first RF output signal, the first and second RF output signals having substantially equal amplitudes;
first and second thin-film mixer elements on the substrate, each mixer element being a balanced mixer comprising a quad diode formed on said substrate and having two mixer inputs and one mixer output, each mixer element having one of the mixer inputs thereof connected with a respective RF signal output and receiving therefrom the respective RF output signal;
a thin-film LO transmission structure on the substrate providing electrical communication between the source of the LO signal and each of the mixer elements, receiving the LO signal and transmitting the LO signal as first and second LO input signals to the other of the inputs of the first and second mixers respectively, said LO transmission structure including an LO phase adjuster element adjustable so that the first and second signal inputs are substantially in phase with each other at the inputs of the mixer elements;
said first and second mixer elements providing first and second mixing output signals, respectively, at the mixer outputs thereof, said first and second mixing output signals including mixer product signals that include an IF signal with a frequency substantially equal to a difference between the frequency of the LO signal and the frequency of the RF signal frequency, and a spur signal having a frequency that is an integral multiple of the frequency of the LO signal,
said IF signal of the first mixing output signal at the first mixer output being substantially 180 degrees out of phase with said IF signal of the second mixing output signal at the second mixer output, and the spur signal of the first mixing output signal at the first mixer output being substantially in phase with the spur signal of the second mixing output signal at the second mixer output; and
a thin film output balun supported on the substrate and having an output and two inputs, each of said inputs being connected with a respective mixer output and receiving the respective mixer output signal therefrom, said output balun producing a shifted mixer output signal from one of the mixing signal outputs, wherein the IF signal in the shifted signal is substantially in phase with the IF signal of the other of the mixer output signals and the spur signal in the shifted signal is substantially 180 degrees out of phase with the spur signal of the other of the mixer output signals;
said output balun combining the shifted mixing signal output with the other of the mixing, output signals so as to produce a circuit output signal wherein the spur signals substantially cancel each other out and the IF signals are combined substantially in phase, said circuit output signal being transmitted via the output of the output balun.

20. The invention according to claim 19, and further comprising an antenna system;
said antenna system receiving an incoming wireless signal that is supplied as the source of the RF signal, or transmitting an outgoing wireless signal derived from the circuit output signal supplied from the balun output.

21. The invention according to claim 20, wherein the frequency of the spur signal is twice the frequency of the LO signal, and the frequency of the spur signal is within 2 GHz of the frequency of the IF signal.
